(19) United States
(12) Patent Application Publication
(10) Pub. No.: US 2012/0318324 A1
(43) Pub. Date: Dec. 20, 2012

(54) Laterally Arranged Multiple-Bandgap Solar Cells

(75) Inventors: Cun-Zheng Ning, Chandler, AZ (US); Derek Caselli, Scottsdale, AZ (US)

(73) Assignee: Arizona Board of Regents, a body corporate of the State of Arizona, Acting for and on behalf of Ariz, Scottsdale, AZ (US)

(21) Appl. No.: 13/517,823

(22) Filed: Jun. 14, 2012

Related U.S. Application Data
(60) Provisional application No. 61/497,278, filed on Jun. 15, 2011.

(51) Int. Cl. H01L 31/052; B82Y 30/00

(52) U.S. Cl. 136/246; 977/762; 977/819; 977/824; 977/948

(57) ABSTRACT

A solar cell assembly can be prepared having one or more laterally-arranged multiple bandgap (LAMB) solar cells and a dispersive concentrator positioned to provide light to a surface of each of the LAMB cells. As described herein, each LAMB cell comprises a plurality of laterally-arranged solar cells each having a different bandgap.

### CROSS-REFERENCE TO RELATED APPLICATIONS

This application claims the benefit of the filing date of U.S. Provisional Application Ser. No. 61/497,278, filed on Jun. 15, 2011, which is hereby incorporated by reference in its entirety.

### STATEMEMENT OF GOVERNMENT FUNDING

The invention described herein was made in part with government support under grant number W911NF-08-1-0471, awarded by US Army Research Office. The United States Government has certain rights in the invention.

### FIELD OF THE INVENTION

The invention generally relates to solar cell assemblies comprising laterally varying alloys and a dispersive concentrator positioned to provide light to the assembly.

### BACKGROUND OF THE INVENTION

High system cost remains the most significant barrier to wide scale adoption of photovoltaic energy. Thin-film solar cells aim to reduce the cost of solar modules by decreasing material consumption, and they have made significant progress in this respect. However, it is argued that the cost of mature thin film photovoltaic modules will, like silicon cells, be dominated by their materials costs, and therefore modules based on high efficiency cells are likely to replace them. (see, M. A. Green, Third Generation Photovoltaics: Advanced Solar Energy Conversion (Springer-Verlag, Berlin, 2006)). Much of the research on high-efficiency terrestrial photovoltaics currently focuses on using expensive tandem cells established for space applications in concentrator systems where their high efficiencies enable reductions in total system costs. The industry standard in this area is Spectrolab's GaInP/GaInAs/Ge triple junction tandem cell, which boasts an efficiency of over 41% under 364 times concentrated sunlight. (see, M. A. Green et al., “Solar Cell Efficiency Tables (version 35)”, Progress in Photovoltaics: Research and Applications 18, 144-150 (2010)). Significant performance improvements with triple junction solar cells are probably not practical, as Gokcen and Loferski estimate that a triple junction cell can obtain about 45% efficiency at concentration levels of 500 to 1000 suns, so the natural strategy is simply to add more junctions. (see, N. A. Gokcen and J. J. Loferski, “Efficiency of Tandem Solar Cell Systems as a Function of Temperature and Solar Energy Concentration Ratio”, Solar Energy Materials 1, 271-286 (1979)). However, the practical number of junctions in a vertically stacked tandem cell is limited by the lattice-matching constraint, the availability of bandgaps at the desired values, and the ability to construct proper tunneling junctions. All these factors make significantly increasing the number of junctions exceedingly difficult.

### SUMMARY OF THE INVENTION

Absorption of different solar spectral components by different bandgaps can also be accomplished in parallel by using Laterally Arranged Multiple Bandgap (LAMB) solar cells, which are not bound by the lattice-matching requirement. Such LAMB cells use a dispersive optics layer to spectrally split the sunlight onto different bandgap regions such that each spectral band is absorbed by the optimized bandgap. The concept of dispersive concentration photovoltaics (DCPV), illustrated schematically in FIG. 1, has been studied since the late 1970s (see, R. L. Moon et al., “Multigap Solar Cell Requirements and the Performance of AlGaAs and Si Cells in Concentrated Sunlight,” in Proceedings of the 13^{th} IEEE Photovoltaic Specialists Conference, Washington, D.C., 1978). One of the most recent attempts related to the current approach is the Very High Efficiency Solar Cell (VHESC) program, in which the researchers combined existing solar cell designs with optics for spectral splitting (see, A. Barnett et al., “Milestones Toward 50% Efficiency Solar Cell Modules,” Presented at the 22^{nd} European Photovoltaic Solar Energy Conference (Institute of Electrical and Electronics Engineers, Milan, Italy, 2007)). They estimated that the structure could achieve 50% overall system efficiency using a low concentration ratio of about 20. Ibid. However, all DCPV approaches so far have used different individual solar cells on different material platforms, arranged spatially to absorb different spectral components (see, Moon et al., supra; W. H. Bloss, M. Griesinger, and E. R. Reinhardt, “Dispersive concentrating systems based on transmission phase holograms for solar applications”, Applied Optics 21, 3739-3742 (1982)). Such approaches, while important in demonstrating the feasibility of DCPV, are too bulky, complex, and expensive to be practical over the long run. A preferable approach would be to fabricate all subcells simultaneously on a single substrate on an integrated platform. Such a capability is provided by recent progress in the growth of alloy nanowires by our group.

Using a “dual gradient” growth method, which combines a temperature gradient with spatial reagent profiling across the surface of a substrate, our group was recently able to grow semiconductor alloy nanowires with the alloy composition continuously varying over a wide range on a single substrate (see, T. Kuykendall, P. Ulrich, S. Aloni, and P. Yang, “Complete composition tunability of InGaN nanowires using a combinatorial approach,” Nat. Mater. 6(12), 951-956 (2007).; A. L. Pan, W. Zhou, E. S. P. Leong, R. B. Liu, A. H. Chin, B. Zou, and C. Z. Ning, “Continuous Alloy-Composition Spatial Grading and Superbroad Wavelength-Tunable Nanowire Lasers on a Single Chip”, Nanoletters 9, 784-788 (2009); and A. L. Pan, R. B. Liu, M. Sun, and C. Z. Ning, “Spatial Composition Grading of Quaternary ZnCdSSe Alloy Nanowires with Tunable Light Emission between 350 and 710 nm on a Single Substrate”, ACS Nano 4, 671-680 (2010)). The corresponding band edge emission wavelength spans the entire visible spectrum range across the substrate length. Such material capability would provide a natural choice as wavelength specific absorption cells for a LAMB design, allowing the absorbing materials in all subcells of a LAMB system to be grown in a single CVD growth (see, C. Z. Ning, A. L. Pan, and R. B. Liu, “Spatially Composition-Graded Alloy Semiconductor Nanowires and Wavelength Specific Lateral-Multijunction Full-Spectrum Solar Cells”, in Proceedings of the 34th IEEE Photovoltaic Specialists Conference (Institute of Electrical and Electronics Engineers, Philadelphia, Pa., 2009), pp. 001492-001495). The pre-patterning of the substrate and the selective deposition of catalyst materials assure that the different subcells are laterally separated. Spatially composition graded CdSₓSe₁₋ₓ and ZnₓCd₁₋ₓS_{y}Se_{1-y} nanowires have already been grown successfully in this way over their complete composition ranges. Similar results may be achieved with CdₓPb₁₋ₓS, which can cover essentially the entire spectral range of interest to photovoltaics.

Spectrum splitting could be accomplished using a number of possible technologies, including holographic and refractive dispersive concentrators. Such dispersive concentrators would be light-weight, inexpensive, and have high optical efficiency over a broad spectral range. They may also accomplish spectral splitting and solar concentration simultaneously with the same optical element, facilitating higher efficiencies, reducing system weight and complexity, and ultimately enabling lower costs

Herein is described the design of a LAMB solar cell based on spatially composition graded nanowires (e.g., CdₓPb₁₋ₓS) to be used in conjunction with a compact dispersive concentrating optical layer.

Accordingly, in one aspect, the disclosure provides solar cell assemblies comprising one or more laterally-arranged multiple bandgap solar (LAMB) cells and a dispersive concentrator positioned to provide light to a surface of each of the LAMB cells, wherein each LAMB cell comprises a plurality of laterally-arranged solar cells each having a different bandgap.

### BRIEF DESCRIPTION OF THE DRAWINGS

FIG. 1 is a schematic of a LAMB solar cell with a spectral splitting concentration optics layer.

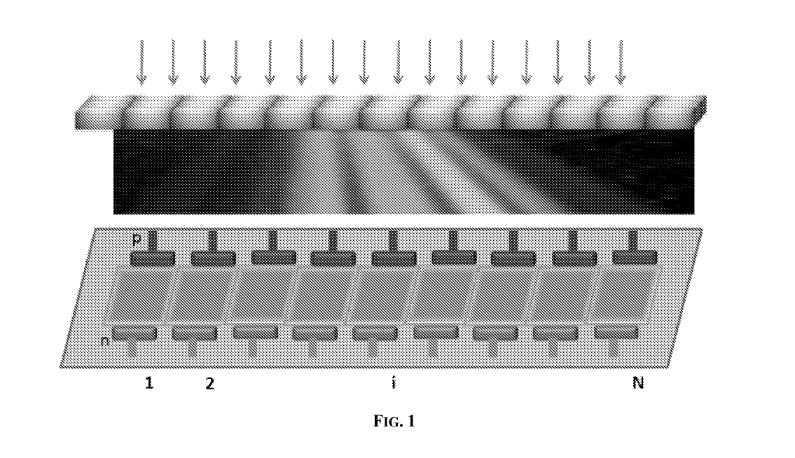

FIG. 2 is an exemplary LAMB solar cell structure.

FIG. 3 is an energy band lineup for the solar cell of Example 1.

FIG. 4 shows current-voltage characteristics of all subcells at varying levels of solar concentration for the solar cell of Example 1.

FIG. 5 shows energy band diagrams at the maximum power point under one sun illumination for the solar cell of Example 1.

FIG. 6 is an exemplary solar cell design having LAMB cells on both sides of a staggered dispersive concentrator optic.

FIG. 7 is a schematic of a LAMB solar cell with a transmission phase hologram optics layer.

FIG. 8 shows the energy band alignment between InGaN and GaP for Design 4 of Example 3.

### DETAILED DESCRIPTION OF THE INVENTION

The solar cell assemblies herein comprise one or more laterally-arranged multiple bandgap (LAMB) solar cells and a dispersive concentrator positioned to provide light to a surface of each of the LAMB cells, wherein each LAMB cell comprises a plurality of laterally-arranged solar cells each having a different bandgap.

In certain embodiments, at least one solar cell comprises an n-contact, a p-contact, and an intrinsic alloy layer disposed between the n-contact and the p-contact. In another embodiment, each solar cell comprises an n-contact, a p-contact, and an intrinsic alloy layer disposed between the n-contact and the p-contact.

It should be understood that when a layer is referred to as being “on” or “over” another layer or substrate, it can be directly on the layer or substrate, or an intervening layer may also be present. It should also be understood that when a layer is referred to as being “on” or “over” another layer or substrate, it may cover the entire layer or substrate, or a portion of the layer or substrate.

It should be further understood that when a layer is referred to as being “directly on” or “directly over” another layer or substrate, the two layers are in direct contact with one another with no intervening layer. It should also be understood that when a layer is referred to as being “directly on” or “directly over” another layer or substrate, it may cover the entire layer or substrate, or a portion of the layer or substrate.

The term “layer” as used herein, means a region of a material, typically grown on a substrate, (e.g., an II-VI semiconductor) that can be uniformly or non-uniformly doped and that can have a uniform or a non-uniform composition across the region.

The term “lateral” as used herein refers to a direction essentially parallel to a surface.

The LAMB cells can comprise at least 2 laterally arranged solar cells; and in certain embodiments, can comprise 2-20; or 2-15; or 2-10; or 2-8; or 2-6 laterally arranged solar cells. In certain embodiments, each LAMB cell comprises four laterally arranged solar cells; or five laterally arranged solar cells; or six laterally arranged solar cells; or seven laterally arranged solar cells; or eight laterally arranged solar cells; or nine laterally arranged solar cells; or ten laterally arranged solar cells.

Each of the solar cells can have a bandgap selected to be between about 0.5 eV and about 3.0 eV. For example, each of the bandgaps can be selected to be between about 0.5 eV and about 2.75 eV; or between about 0.5 eV and about 2.50 eV; or between about 0.5 eV and about 2.25 eV; or between about 0.65 eV and about 2.75 eV; or between about 0.65 eV and about 2.50 eV; or between about 0.60 eV and about 2.30 eV; or between about 0.65 eV and about 2.25 eV; between about 0.75 eV and about 2.75 eV; or between about 0.75 eV and about 2.50 eV; or between about 0.75 eV and about 2.25 eV. The term “bandgap of the solar cell” as used herein means the energy of the least energetic photons that can be usefully absorbed by the composition-graded alloy nanowires in the solar cell. In certain embodiments, the bandgap of each of the solar cells can increase (or decrease) from one end of the LAMB cell to the other end of the LAMB cell.

For example, where the LAMB cell comprises six laterally arranged solar cells, each of the solar cells can have a bandgap between about 2.07 and 2.27 eV; 1.57 and 1.77 eV; 1.33 and 1.53 eV; 1.07 and 1.37 eV; 0.85 and 1.05 eV; and 0.60 and 0.80 eV. In another example, where the LAMB cell comprises six laterally arranged solar cells, each of the solar cells can have a bandgap between about 2.22 and 2.42 eV; 1.82 and 2.02 eV; 1.55 and 1.75 eV; 1.33 and 1.53 eV; 1.11 and 1.31 eV; and 0.93 and 1.13 eV. In another example, where the LAMB cell comprises six laterally arranged solar cells, each of the solar cells can have a bandgap between about 2.18 and 2.38 eV; 1.68 and 1.88 eV; 1.31 and 1.51 eV; 1.03 and 1.23 eV; 0.80 and 1.00 eV; and 0.60 and 0.80 eV.

In another example, where the LAMB cell comprises five laterally arranged solar cells, each of the solar cells can have a bandgap between about 2.01 and 2.21 eV; 1.56 and 1.76 eV; 1.25 and 1.45 eV; 0.95 and 1.15 eV; and 0.67 and 0.87 eV.

The LAMB cells can comprise a substrate and a laterally varying alloy layer formed over a surface of the substrate, wherein the alloy layer comprises the preceding nanowires.

The substrate can be any material suitable for the desired application. For example, silica and alumina based glasses, and indium-tin-oxide glass (ITO glass) can be used. The ITO layer can, for example, have a thickness between about 100 nm and about 200 nm. As one skilled in the art would recognize, thicker layers of ITO may be used provided that the selected layer is substantially transparent to sunlight such that incident light is absorbed by the laterally varying alloy layer, and not in the ITO.

For example, the laterally varying alloy layer may comprise any of the Laterally Varying II-VI Alloys as described in International Publication No. WO 2010/054231, which is hereby incorporated by reference in its entirety. The n-contacts in each solar cell can be disposed between the substrate and the laterally varying alloy layer; or the p-contacts in each solar cell can be disposed between the substrate and the laterally varying alloy layer. In other embodiments, the substrate comprises the n-contact or the p-contact. In each case, the other of the n-contact and the p-contact in each solar cell can be disposed over the laterally varying alloy layer.

The elemental composition of the laterally varying alloy layer can continuously vary between a first compound or alloy at a first position over the surface of the substrate and a second compound or alloy at a second position over the surface of the substrate. Different compound combinations can be used for different intervals to achieve different bandgaps of different alloys.

The lateral bandgap variation of the alloy layer can be with respect to a pair of compounds selected from the constituent compounds of the first and second compounds or alloys. From the first to second positions, one compound of the first pair continuously increases in compositional abundance of the alloy layer and the other compound of the first pair continuously decreases in compositional abundance of the alloy layer.

For example, for an alloy layer comprising CdSₓSe₁₋ₓ, the composition of the alloy layer can continuously change from a first to second position with respect to a pair of constituent II-VI compounds, in this case, CdS and CdSe. The continuous variation in the composition of the alloy layer between any two points over the substrate can be linear or nonlinear, or a combination thereof or other forms depending on a given application.

In certain embodiments, the intrinsic alloy layer of the solar cells comprises nanowires. Such nanowires may be, for example, II-VI alloy nanowires or III-V alloy nanowires.

The term “II-VI alloy” as used herein means an alloy where the constituent elements are selected from Groups HA, IIB, and VIA, of the periodic table, wherein at least one constituent element is selected from Groups IIA and/or IIB of the periodic table and at least one constituent element is selected from Group VIA of the periodic table. Examples of II-VI alloys include, but are not limited to (a) binary II-VI compounds (i.e., “II-VI compounds”) such as, but not limited to, Cadmium selenide (CdSe), Cadmium sulfide (CdS), Cadmium telluride (CdTe), Zinc oxide (ZnO), Zinc selenide (ZnSe), Zinc sulfide (ZnS), and Zinc telluride (ZnTe); (b) ternary alloys such as, but not limited to, Cadmium zinc telluride (CdZnTe, CZT), Mercury cadmium telluride (HgCdTe), Mercury zinc telluride (HgZnTe), and Mercury zinc selenide (HgZnSe); and (c) quaternary alloys such as, but not limited to, Cadmium mercury selenide telluride (CdHgSeTe) and Cadmium zinc selenide telluride (CdZnSeTe).

The term “III-V alloy” as used herein means an alloy where the constituent elements are selected from Groups IIIA and VA of the periodic table, wherein at least one constituent element is selected from Group IIIA of the periodic table and at least one constituent element is selected from Group VA of the periodic table. Examples of III-V alloys include, but are not limited to (a) binary alloys such as, but not limited to, Aluminum antimonide (AlSb), Aluminum arsenide (AlAs), Aluminum nitride (AlN), Aluminum phosphide (AlP), Boron nitride (BN), Boron phosphide (BP), Boron arsenide (BAs), Gallium antimonide (GaSb), Gallium arsenide (GaAs), Gallium nitride (GaN), Gallium phosphide (GaP), Indium antimonide (InSb), Indium arsenide (InAs), Indium nitride (InN), and Indium phosphide (InP); (b) ternary alloys such as, but not limited to, Aluminum gallium arsenide (AlGaAs), Indium gallium arsenide (InGaAs), Aluminum indium arsenide (AlInAs), Aluminum indium antimonide (AlInSb), Gallium arsenide nitride (GaAsN), Gallium arsenide phosphide (GaAsP), Aluminum gallium nitride (AlGaN), Aluminum gallium phosphide (AlGaP), Indium gallium nitride (InGaN), Indium arsenide antimonide (InAsSb), and Indium gallium antimonide (InGaSb); (c) quaternary alloys such as, but not limited to, Aluminum gallium indium phosphide (AlGaInP, also InAlGaP, InGaAlP, AlInGaP), Aluminum gallium arsenide phosphide (AlGaAsP), Indium gallium arsenide phosphide (InGaAsP), Aluminum indium arsenide phosphide (AlInAsP), Aluminum gallium arsenide nitride (AlGaAsN), Indium gallium arsenide nitride (InGaAsN), and Indium aluminum arsenide nitride (InAlAsN); and (d) quinary alloys such as, but not limited to, Gallium indium nitride arsenide antimonide (GaInNAsSb). Higher order alloys include, for example, the senary alloy Indium gallium aluminum arsenide antimonide phosphide InGaAlAsSbP.

Particular examples include, but are not limited to CdₓPb₁₋ₓS nanowires, ZnₓCd_{y}Hg_{1-x-y}Te nanowires, AlₓGa_{y}In_{1-x-y}As nanowires, GaₓIn₁₋ₓP_{y}As_{1-y} nanowires, or InₓGa₁₋ₓN nanowires. In one embodiment, the nanowires are CdₓPb₁₋ₓS nanowires. In another embodiment, the nanowires are ZnₓCd_{y}Hg_{1-x-y}Te nanowires. In another embodiment, the nanowires are AlₓGa_{y}In_{1-x-y}As nanowires. In another embodiment, the nanowires are GaₓIn₁₋ₓP_{y}As_{1-y} nanowires. In another embodiment, the nanowires are InₓGa₁₋ₓN nanowires. In certain other embodiments, the nanowires are spatially-composition graded nanowires. The term “nanowire” as used herein means structures that have a lateral size of less than about 1000 nm (e.g., about 1-100 nm) and an unconstrained longitudinal size. For example, nanowires can have an aspect ratio of 1000 or more. In certain embodiments, the nanowires are about 2 μm to about 5 μm long. In other embodiments, when the intrinsic alloy layer comprises nanowires, such should be sufficiently dense to fill greater than about 50% of the substrate area.

For example, when the nanowires are ZnₓCd_{y}Hg_{1-x-y}Te nanowires, the bandgap of each solar cell can be selected to be between about 0 eV and about 2.26 eV. In another example, when the nanowires are AlₓGa_{y}In_{1-x-y}As nanowires, the bandgap of each solar cell can be selected to be between about 0.35 eV and about 2.17 eV. In another example, when the nanowires are GaₓIn₁₋ₓP_{y}As_{1-y} nanowires the bandgap of each solar cell can be selected to be between about 0.35 eV and about 2.26 eV.

In other embodiments, each of the plurality of laterally-arranged solar cells can comprise a laterally varying alloy layer, as described according to any of the preceding embodiments.

The n-contact for each of the solar cells can comprise an n-CdS, n-ZnSe or n-ZnS layer. The p-contact for each of the solar cells can comprise a p-ZnTe, p-CdTe, p-Si, or p-Ge layer. In certain embodiments, the n-contact for each of the solar cells can comprise an n-ZnS layer and the p-contact for each of the solar cells can comprise a p-ZnTe layer. In certain embodiments, the n-contact for each of the solar cells can comprise an n-ZnS layer and the p-contact for each of the solar cells can comprise p-Ge. The n-contact and p-contact layers should be suitably thick to cover the intrinsic alloy layer (e.g., nanowires). For example, the contacts should be at least 200 nm thick (e.g., 200 nm-300 nm thick).

In any of the embodiments of the n-contacts and/or p-contacts, the n-contacts and p-contacts can be highly doped, for example, having net donor and acceptor concentrations of greater than about 10¹⁷ cm⁻³. In certain embodiments, the net donor and acceptor concentrations can be greater than about 10¹⁸ cm⁻³. In certain embodiments, the net donor and acceptor concentrations can be greater than about 10¹⁹ cm⁻³. In certain embodiments, the net donor and acceptor concentrations can be between about 10¹⁷ cm⁻³ and about 10²⁰ cm⁻³; or between about 10¹⁷ cm⁻³ and about 10¹⁹ cm⁻³; or between about 10¹⁷ cm⁻³ and about 10¹⁸ cm⁻³; or between about 10¹⁸ cm⁻³ and about 10¹⁹ cm⁻³.

The term “p-doped” as used herein means atoms have been added to the material to increase the number of free positive charge carriers.

The term “n-doped” as used herein means atoms have been added to the material to increase the number of free negative charge carriers.

In another embodiment, solar cell assemblies herein comprise those wherein at least one solar cell comprises a heterojunction p-n junction. The term “p-n junction” as used herein means an assembly comprising two semiconducting materials layers in contact with one another, where one layer is p-doped and the other layer is n-doped. Each layer can be doped as is understood by one skilled in the art in view of the semiconducting content of each layer.

In one embodiment, each solar cell comprises a heterojunction p-n junction. A “heterojunction p-n junction” as used herein is a p-n junction as defined herein wherein the two semiconducting materials comprising the p-layer and n-layer, respectively, have different alloy composition (notwithstanding the doping content of the layers).

In the preceding embodiments, either the p-layer or the n-layer can comprise nanowires. In one particular embodiment, the n-layer of the heterojunction p-n junction comprises nanowires. When the layers of the layers of the p-n junction comprise nanowires, the nanowire can comprise n-doped CdₓPb₁₋ₓS nanowires, n-doped ZnₓCd_{y}Hg_{1-x-y}Te nanowires, n-doped AlₓGa_{y}In_{1-x-y}As nanowires, n-doped GaₓIn₁₋ₓP_{y}As_{1-y} nanowires, or n-doped InₓGa₁₋ₓN nanowires.

In another embodiment, the n-layer can comprise n-doped CdₓPb₁₋ₓS nanowires.

In another embodiment, the n-layer can comprise n-doped ZnₓCd_{y}Hg_{1-x-y}Te nanowires.

In another embodiment, the n-layer can comprise n-doped AlₓGa_{y}In_{1-x-y}As nanowires.

In another embodiment, the n-layer can comprise n-doped GaₓIn₁₋ₓP_{y}As_{1-y} nanowires.

In another embodiment, the n-layer can comprise n-doped InₓGa₁₋ₓN nanowires. For example, when the nanowires are InₓGa₁₋ₓN nanowires, the bandgap of each solar cell can be selected to be between about 0.70 eV and about 2.30 eV.

In any of the preceding embodiments, the p-layer of the heterojunction p-n junction can comprise p-GaP.

In one embodiment, the p-layer of the heterojunction p-n junction comprises p-GaP and the n-layer comprises n-doped InₓGa₁₋ₓN nanowires.

In another embodiment, solar cell assemblies herein comprise those wherein at least one solar cell comprises a heterojunction p-i-n junction. In one embodiment, each solar cell comprises a heterojunction p-i-n junction.

The term “p-i-n junction” as used herein means an assembly comprising three semiconducting materials layers in contact with one another, where one layer is p-doped, a second layer is n-doped, and the third layer is an intrinsic semiconductor layer (“i-layer”), where the i-layer is disposed between the p-layer and the n-layer. Each layer can be doped as is understood by one skilled in the art in view of the semiconducting content of each layer. The term “intrinsic” as used herein means a material in which the concentration of charge carriers is characteristic of the material itself rather than the content of impurities (or dopants). A “heterojunction p-n junction” as used herein is a p-i-n junction as defined herein wherein the two semiconducting materials comprising the p-layer and n-layer, respectively, have different alloy composition (notwithstanding the doping content of the layers); the i-layer may comprise the same or a different alloy with respect to the p-layer and/or n-layer.

In the preceding embodiments, the p-layer, the n-layer, and/or the i-layer can comprise nanowires. In one particular embodiment, the n-layer and the i-layer of the heterojunction p-i-n junction comprises nanowires.

When the n-layer of the heterojunction p-i-n junction comprises nanowires, the nanowires can comprise n-doped CdₓPb₁₋ₓS nanowires, n-doped ZnₓCd_{y}Hg_{1-x-y}Te nanowires, n-doped AlₓGa_{y}In_{1-x-y}As nanowires, n-doped GaₓIn₁₋ₓP_{y}As_{1-y} nanowires, or n-doped InₓGa₁₋ₓN nanowires.

In another embodiment, the n-layer can comprise n-doped CdₓPb₁₋ₓS nanowires.

In another embodiment, the n-layer can comprise n-doped ZnₓCd_{y}Hg_{1-x-y}Te nanowires.

In another embodiment, the n-layer can comprise n-doped AlₓGa_{y}In_{1-x-y}As nanowires.

In another embodiment, the n-layer can comprise n-doped GaₓIn₁₋ₓP_{y}As_{1-y} nanowires.

In another embodiment, the n-layer can comprise n-doped InₓGa₁₋ₓN nanowires. For example, when the nanowires are InₓGa₁₋ₓN nanowires, the bandgap of each solar cell can be selected to be between about 0.70 eV and about 2.30 eV.

When the i-layer of the heterojunction p-i-n junction comprises nanowires, the nanowires can comprise intrinsic CdₓPb₁₋ₓS nanowires, intrinsic ZnₓCd_{y}Hg_{1-x-y}Te nanowires, intrinsic AlₓGa_{y}In_{1-x-y}As nanowires, intrinsic GaₓIn₁₋ₓP_{y}As_{1-y} nanowires, or intrinsic InₓGa₁₋ₓN nanowires.

In another embodiment, the i-layer can comprise intrinsic CdₓPb₁₋ₓS nanowires.

In another embodiment, the i-layer can comprise intrinsic ZnₓCd_{y}Hg_{1-x-y}Te nanowires.

In another embodiment, the i-layer can comprise intrinsic AlₓGa_{y}In_{1-x-y}As nanowires.

In another embodiment, the i-layer can comprise intrinsic GaₓIn₁₋ₓP_{y}As_{1-y} nanowires.

In another embodiment, the i-layer can comprise intrinsic InₓGa₁₋ₓN nanowires. For example, when the nanowires are InₓGa₁₋ₓN nanowires, the bandgap of each solar cell can be selected to be between about 0.70 eV and about 2.30 eV.

In certain embodiments, each of the n-layer and the i-layer comprise n-doped and intrinsic layers, respectively, of the same semiconducting material (e.g., the layers comprise n-doped InₓGa₁₋ₓN nanowires and intrinsic InₓGa₁₋ₓN nanowires, respectively).

In any of the preceding embodiments, the p-layer of the heterojunction p-n junction can comprise p-GaP.

In one embodiment, the p-layer of the heterojunction p-n junction comprises p-GaP, the n-layer comprises n-doped InₓGa₁₋ₓN nanowires, and the i-layer comprises intrinsic InₓGa₁₋ₓN nanowires.

In any of the embodiments of the n-layer and/or p-layers of the heterojunction p-n or heterojunction p-i-n junctions, the n-layer and p-layer can be highly doped, for example, having net donor and acceptor concentrations of greater than about 10¹⁷ cm⁻³. In certain embodiments, the net donor and acceptor concentrations can be greater than about 10¹⁸ cm⁻³. In certain embodiments, the net donor and acceptor concentrations can be greater than about 10¹⁹ cm⁻³. In certain embodiments, the net donor and acceptor concentrations can be between about 10¹⁷ cm⁻³ and about 10²⁰ cm⁻³; or between about 10¹⁷ cm⁻³ and about 10¹⁹ cm⁻³; or between about 10¹⁷ cm⁻³ and about 10¹⁸ cm⁻³; or between about 10¹⁸ cm⁻³ and about 10¹⁹ cm⁻³.

Suitable metal contacts may be formed in communication with the preceding assemblies, such as with n- and p-contacts, respectively or the p-layer and the n-layer, respectively. Metals which may be used for metal contacts include, but are not limited to, gold, silver, copper, and combinations thereof. Metal contacts can be formed as layers having a thickness between about 100 nm and 500 nm (e.g., 200 nm). Or, combination contacts can be formed comprising a thin layer of copper (e.g., 1-5 nm) covered by a gold layer having a thickness between about 100 nm and 500 nm (e.g., 200 nm).

Any of a number of dispersive concentrators can be disposed between the two LAMB cells. For example, the dispersive concentrator can comprise one or more spectrally selective holographic planar concentrators. Dispersive concentrating elements based on transmission phase holograms, as found in the literature, are often made using dichromated gelatin (see, for example, Bloss et al., “Dispersive concentrating systems based on transmission phase holograms for solar applications,” Applied Optics 21 (20), 3739-3742 (1982); J. E. Ludman et al., “The Optimization of a Holographic System for Solar Power Generation,” Solar Energy 60 (1), 1-9 (1997); Riccobono et al., Holography for the New Millenium (Springer-Verlag, New York, 2002); Kostuk et al., “Spectral shifting and holographic planar concentrators for use with photovoltaic solar cells,” Proceedings of SPIE 6649, 664901 (2007); and Frölich et al., “Fabrication and test of a holographic concentrator for two color PV-operation,” Proceedings of the International Society for Optical Engineering 2255, Freiburg, Germany, 1994, pp. 812-821, each of which is hereby incorporated by reference in its entirety), or “photopolymers” such as those made by DuPont or Polaroid can also be used [8]. One example is Dupont's HRF series of photopolymers, described in W. K. Smothers et al., “Hologram recording in Dupont's new photopolymer materials,” in Practical Holography IV, S. A. Benton, ed., January 18-19, Los Angeles, Calif., SPIE OE/Laser Conference Proceedings 1212-04, 30-39 (1990), which is hereby incorporated by reference in its entirety. The hologram itself is recorded optically using chemical processing techniques similar to those in photography (see, Bloss, Riccobono, and Frölich, supra).

In certain embodiments, the dispersive concentrator comprises the same number of spectrally selective holographic planar concentrators as the number of solar cells in each LAMB cell. Each spectrally selective holographic planar concentrator may be in optical communication with only one solar cell of each LAMB, wherein the solar cells in communication with each of the spectrally selective holographic planar concentrators have essentially the same bandgap. Suitably, the wavelengths of light selected by each spectrally selective holographic planar concentrator correspond to the bandgap of the solar cell in optical communication with the spectrally selective holographic planar concentrator. The phrase “corresponds to the bandgap of the solar cell” as used herein means that for a photon with the given wavelength, it has energy equal to or greater than the bandgap of the solar cell, but not greater than that of any of the other solar cells with larger bandgaps. The bandgaps of the solar cells and the minimum photon energies selected by the optical elements of the dispersive concentrator should be selected to correspond as closely as possible to minimize thermalization, transmission, and connection losses. For example, mismatches between the minimum photon energies and bandgaps of the solar cells of about +/−10% of the bandgap may be tolerated.

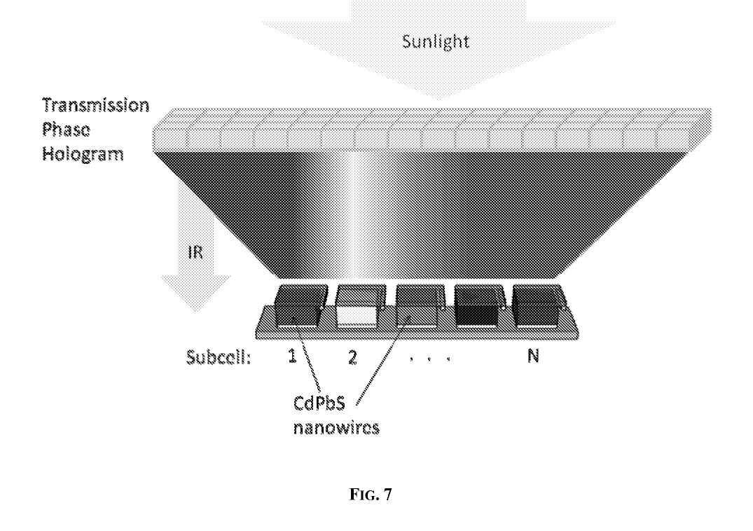

In one embodiment as show in FIG. 7, the solar cell assembly comprises one laterally-arranged multiple bandgap solar (LAMB) cell and a dispersive concentrator (e.g., a transmission phase hologram) positioned to provide light to a surface of the LAMB cell, wherein the LAMB cell comprises a plurality of laterally-arranged solar cells each having a different bandgap, and wherein each solar cell comprises an n-contact, a p-contact, and an intrinsic II-VI alloy layer (e.g., CdₓPb₁₋ₓS) disposed between the n-contact and the p-contact. The dispersive concentrator may be situated above a surface of the LAMB cell, and may be separated from the LAMB cell surface by one or more optically transparent spacer layers, provided the optically transparent spacer layer is essentially transparent to the wavelengths of light collected by the LAMB cell. The transparent spacer layers may comprise, for example, air or a low refractive index material. In certain embodiments, the transparent spacer layers comprise air.

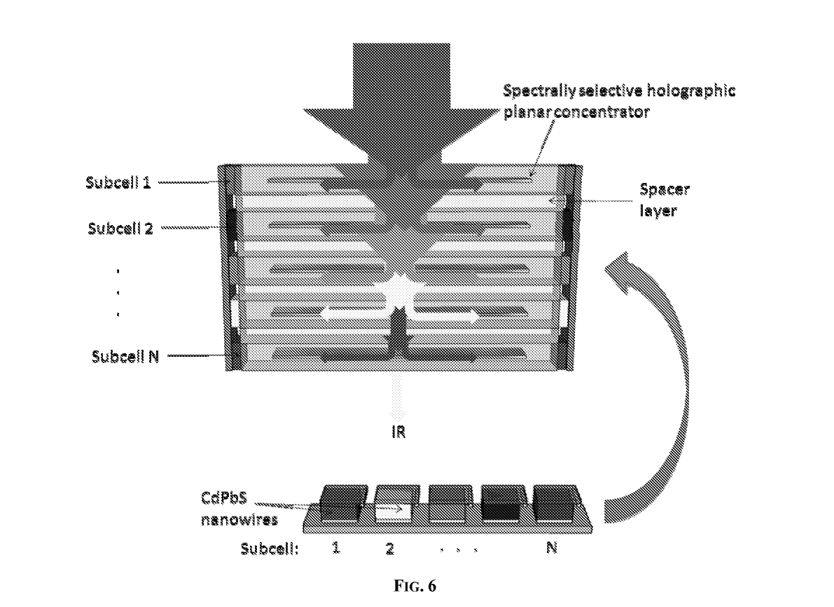

In one embodiment, the solar cell assembly comprises two laterally-arranged multiple bandgap solar (LAMB) cells and a dispersive concentrator positioned to provide light to a surface of each of the LAMB cells (e.g, between the LAMB cells as shown in FIG. 6), wherein each LAMB cell comprises a plurality of laterally-arranged solar cells each having a different bandgap, and wherein each solar cell comprises an n-contact, a p-contact, and an intrinsic II-VI alloy layer disposed between the n-contact and the p-contact.

In another embodiment, the solar cell assembly comprises two laterally-arranged multiple bandgap solar (LAMB) cells and a dispersive concentrator positioned to provide light to a surface of each of the LAMB cells (e.g, between the LAMB cells as shown in FIG. 6), wherein each LAMB cell comprises a plurality of laterally-arranged solar cells each having a different bandgap, and wherein each solar cell comprises an n-contact, a p-contact, and an intrinsic CdₓPb₁₋ₓS alloy layer disposed between the n-contact and the p-contact.

In another embodiment, the solar cell assembly comprises two laterally-arranged multiple bandgap solar (LAMB) cells and a dispersive concentrator positioned to provide light to the surface of each of the LAMB cells (e.g, between the LAMB cells as shown in FIG. 6), wherein each LAMB cell comprises a plurality of laterally-arranged solar cells each having a different bandgap, and wherein each solar cell comprises an n-contact, a p-contact, and an intrinsic CdₓPb₁₋ₓS nanowire layer disposed between the n-contact and the p-contact, wherein each re-contact comprises n-ZnS, and each p-contact independently comprises p-ZnTe, p-CdTe, p-Si, or p-Ge.

The LAMB cells may be fabricated using, for example, randomly oriented or vertical nanowire arrays. Randomly oriented nanowires may be transferred between substrates by contact printing or the Langmuir-Blodgett techniques known to those skilled in the art before deposition of the contact materials. Spin-on-glass, Si₃N₄ or SiO₂ deposited by CVD can be used to isolate the p and n-type contacts. The insulating material can be etched to expose the nanowires prior to contact deposition to ensure good electrical contact. Alternatively, vertical nanowire arrays can be obtained using growth templates such as those made from anodized aluminum oxide (AAO). The AAO would serve essentially the same purpose as the dielectric material for the randomly oriented wires, isolating the p and n-type contact materials from each other and providing a planar surface for film deposition. The AAO can be etched using NaOH to expose the nanowires before depositing the contact materials to obtain better electrical contact.

For example, in the design of FIG. 6, the solar cells could be mechanically attached to the edge of the dispersive concentrator and the entire structure encapsulated using standard materials and techniques (e.g., using ethylene-vinyl acetate copolymer (EVA), and Tedlar®, polyvinyl fluoride (PVF), as a backing) Sheet glass provides a durable and transparent front surface, while the module frame may be aluminum or some other material). For a design such as that shown in FIG. 7, a frame could hold the dispersive concentrator some distance from the LAMB solar cell, and the module would consist of a plurality of such assemblies.

### EXAMPLES

### Example 1

### Solar Cell Design

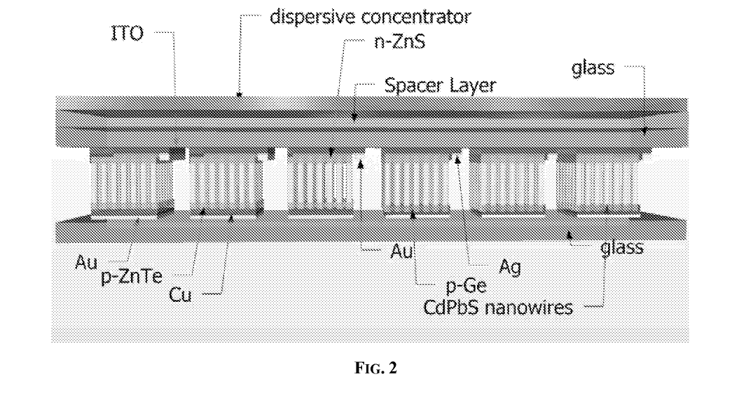

The range of bandgaps available using CdₓPb₁₋ₓS stretches approximately from 0.4 eV (PbS) to 2.4 eV (CdS) (see, H. Rahnamai and J. N. Zemel, “PbS—Si Heterojunction II: Electrical Properties”, Thin Solid Films 74, 17-22 (1980); Z. Liu et al., “Room temperature photocurrent response of PbS/InP heterojunction”, Applied Physics Letters 95, 231113 (2009); ATLAS User's Manual: Device Simulation Software, SILVACO International, Santa Clara, Calif., 2007; and T. L. Chu and S. S. Chu, “Thin Film II-VI Photovoltaics”, Solid State Electronics 38, 533-549 (1995)). To design the subcells for optimal series connections, it is necessary to choose the bandgaps such that equal numbers of photons impinge on each, assuming the number of electron-hole pairs extracted per incident photon is approximately the same for all subcells. Six subcells were chosen for the simulation, with a minimum bandgap of 0.7 eV, which sets the composition of all subcells as shown in Table 1. The layout of the entire structure is shown in FIG. 2.

The structure of each subcell consists of a transparent top contact, a window layer, intrinsic CdₓPb₁₋ₓS nanowires, a back-surface field (BSF) layer, and a rear electrode. The heavily doped window and BSF layers create electric fields in the intrinsic nanowires which accelerate electrons and holes towards the negative and positive electrodes respectively. Ideally, they should also readily accept charge carriers of one type from the nanowires while blocking carriers of the opposite type. This prevents electrons generated near the p-contact or holes generated near the n-contact from diffusing toward the wrong electrode, thereby decreasing the output of the cell. Both ends of the nanowires could be embedded inside the doped layers to improve the contacts and facilitate carrier collection.

TABLE 1
CdₓPb₁₋ₓS composition and material data by subcell

| Subcell | Composition | Bandgap (eV) | Electron Affinity (eV) |
|---|---|---|---|
| 1 | Cd_{0.89}Pb_{0 11}S | 2.17 | 4.36 |
| 2 | Cd_{0.64}Pb_{0.36}S | 1.67 | 4.07 |
| 3 | Cd_{0.52}Pb_{0 48}S | 1.43 | 3.93 |
| 4 | Cd_{0.39}Pb_{0.61}S | 1.17 | 3.77 |
| 5 | Cd_{0.28}Pb_{0.72}S | 0.95 | 3.64 |
| 6 | Cd_{0.16}Pb_{0.84}S | 0.70 | 3.50 |

The broad range of bandgaps and electron affinities spanned by these nanowires poses a design challenge for effective extraction of photogenerated carriers. The window and BSF layers are required to be heavily doped and have minimal band offsets with the band edges of the carriers they are designed to extract. This poses a greater challenge to the p-contacts because the positions of the valence band edges vary through a larger range than the conduction band edges. This, in addition to the fact that nearly all common transparent conductors are n-type, makes it convenient to choose the top contact to be n-type. The electron affinities of CdₓPb₁₋ₓS for many subcells are relatively small; therefore a transparent n-type conductor with a low work function or a highly doped semiconductor with a low electron affinity is used for the window layer. The most common transparent conductor, indium tin oxide (ITO), has a work function of approximately 4.7 eV, which is too large to effectively extract electrons from CdₓPb₁₋ₓS (see, E. Kymakis and G. A. Amaratunga, “Single-wall carbon nanotube/conjugated polymer photovoltaic devices”, Applied Physics Letters 80, 112-114 (2002)). The bandgap of ZnS, at 3.66 eV, is large enough for the material to be transparent for all wavelengths of interest, and it has an appropriately small electron affinity at 3.9 eV. ZnS can be n-doped above 10¹⁹ cm⁻³ (see, U. V. Desnica, “Doping Limits in II-VI Compounds—Challenges, Problems and Solutions”, Progress in Crystal Growth and Characterization 36, 291-357 (1998)), but unfortunately its conductivity is still an order of magnitude below that of ITO (see, Y. Imai, A. Watanabe, and I. Shimono, “Comparison of electronic structures of doped ZnS and ZnO calculated by a first-principle pseudopotential method”, Journal of Materials Science: Materials in Electronics 14, 149-156 (2003); and H. Ohta et al., “Highly electrically conductive indium-tin-oxide thin films epitaxially grown on yttria-stabilized zirconia (100) by pulsed-laser deposition”, Applied Physics Letters 76, 2740-2742 (2000)). Therefore, the most appropriate top contact structure consists of a thin film of heavily-doped ZnS as a window layer, deposited on an ITO-coated glass substrate, which serves as the transparent n-contact.

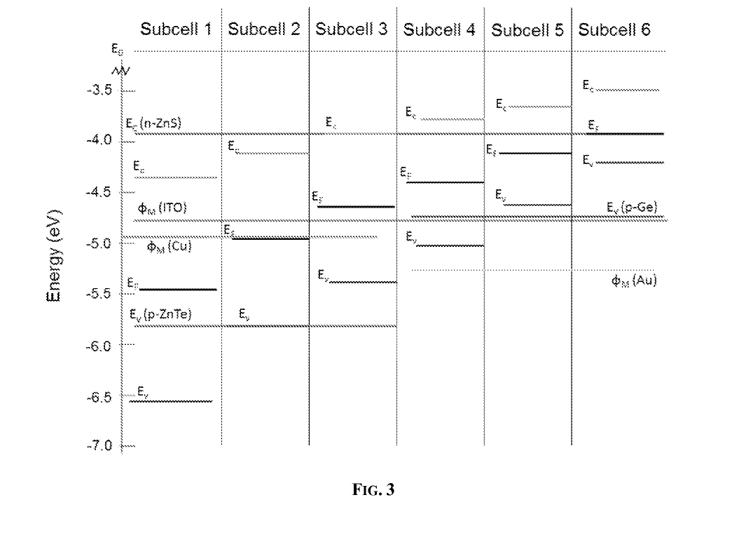

For the BSF layers and p-contacts, it is not possible to use the same materials across all subcells due to the large range through which the positions of the valence band edges vary. Therefore, p-ZnTe is used for the BSF layers of the three largest bandgap subcells and p-Ge is used for the three smallest bandgap subcells (FIG. 2). The energy band lineups are shown in FIG. 3.

Lastly, materials are selected for the final metal-semiconductor contacts. Cu is an appropriate choice of metal to contact p-ZnTe because it acts as an acceptor in this material, and therefore diffusion of the Cu metallization into the ZnTe helps to create a highly doped layer near the surface that facilitates tunneling (see, A. Mondal, B. E. McCandless, and R. W. Birkmire, “Electrochemical deposition of thin ZnTe films as a contact for CdTe solar cells”, Solar Energy Materials and Solar Cells 26, 181-187 (1992)). Au is used to form ohmic contacts to p-Ge in GaInP/GaInAs/Ge tandem cells (see, D. J. Friedman and J. M. Olson, “Analysis of Ge Junctions for GaInP/GaAs/Ge Three junction Solar Cells”, Progress in Photovoltaics: Research and Applications 9, 179-189 (2001)), making it a natural choice to contact p-Ge here as well.

### Example 2

### Simulations

Computer simulations of the solar cell described above were conducted using Silvaco ATLAS device simulation software (ATLAS, version 5.15.34.C, Silvaco Data Systems, Inc.: 2009). The simulated illumination source was the ASTM G173 standard air mass 1.5 direct spectrum (see, Emery, Keith and Meyers, Daryl, “Solar Spectral Irradiance: Air Mass 1.5” (National Renewable Energy Laboratory, 2009). See, for example, web site rredc.nrel.gov/solar/spectra/am1.5/ASTMG173/ASTMG173.html.

Due to practical considerations, a number of simplifying assumptions were made:
1) In all cases, ideal ohmic contacts to the window and BSF layers were assumed. These layers were all simulated using dopant concentrations of 10¹⁹ cm⁻³.
2) Spectral splitting was assumed to occur with no optical loss other than the rejection of diffuse sunlight, and reflection at the top interfaces of the subcells was ignored, equivalent to assuming an ideal anti-reflective coating.
3) All subcells were assumed to have equal surface areas.
4) For the sake of simplicity, the CdₓPb₁₋ₓS absorbing material was assumed to be a thin film 2 μm thick for all subcells in our simulation. Thus one might argue that a spatial filling factor smaller than unity should be applied if it is to properly simulate a nanowire array due to the existence of voids. However, studies have shown that nanowire arrays have significantly enhanced light absorption properties compared to continuous thin films for certain spatial filling factors (see, M. D. Kelzenberg et al., “Enhanced absorption and carrier collection in Si wire arrays for photovoltaic applications”, Nature Materials 9, 239-244 (2010); and N. Lagos, M. M. Sigalas, and D. Niarchos, The optical absorption of nanowire arrays, Photonics and Nanostructures: Fundamentals and Applications (2010), doi: 10.1016/j.photonics.2010.09.005). For the case of Si nanowires, it has been shown that a vertical nanowire array with an areal filling ratio of 0.2 or 0.44 has superior absorption characteristics to a planar Si surface. The final balance of the two effects would modify the simulation results that follow, depending upon the spatial filling factor of the nanowire array. In addition, the effective conductivity of the nanowire layers may be somewhat smaller than that of a continuous film due to surface scattering and possibly, in the case of randomly oriented nanowires, small contact areas between wires. This effect has been studied by performing simulations with various levels of reduced carrier mobilities.
5) Material bandgaps, electron affinities, wavelength dependent real and imaginary parts of the refractive indices, effective densities of states, and carrier mobilities for CdₓPb₁₋ₓS were calculated by simple linear interpolation based on the composition fraction.
6) The composition of the CdₓPb₁₋ₓS nanowires was assumed to be fixed in any given subcell.
7) Only Shockley-Read-Hall recombination was considered, with fixed carrier lifetimes of 10 ns for all materials.

The simulations were performed for solar concentration ratios of one, 25, 100, and 240, defined as the area of the solar collector (the dispersive concentrator or DC) divided by the area of the solar cell. Note that spectral splitting entails that all sunlight within a given spectral range incident on the DC is focused on a single subcell. Given that there are six subcells of equal areas, this means that the portion of the spectrum assigned to any individual subcell is effectively already concentrated by a factor of six even for a solar concentration ratio of one. The efficiencies under various levels of solar concentration are shown in Table 2.

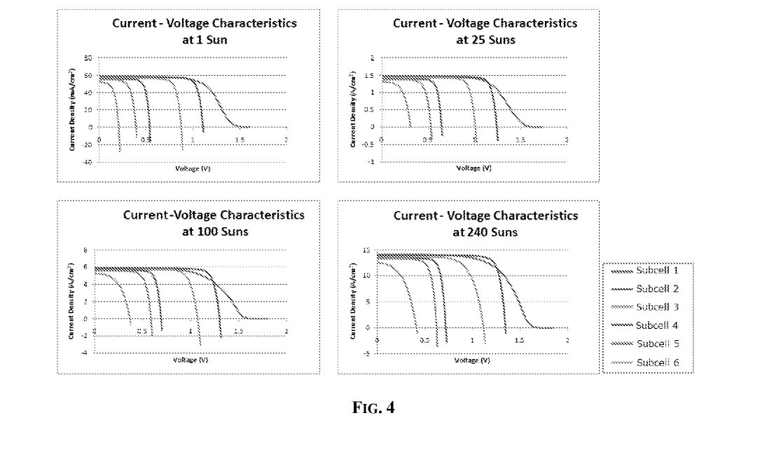

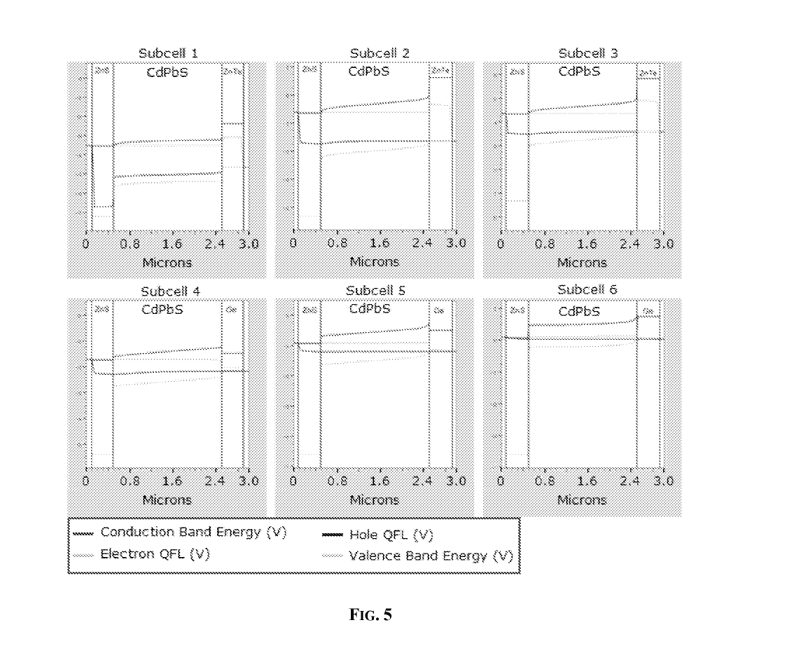

The graphs in FIG. 4 show the current-voltage characteristics for all the subcells individually at the various concentration ratios. Several features of these curves bear examination. The current-voltage characteristic of the first (largest bandgap) subcell flattens as the current density approaches zero, an effect known as “roll-over”. This is due to the large valence band offset at the interface with the BSF layer; the valence band of p-ZnTe is significantly above that of Cd_{0.89}Pb_{0.11}S. A significant improvement in the performance of this solar cell could be achieved if a suitable alternative to p-ZnTe were found for the first subcell with its valence band closer to that of Cd_{0.89}Pb_{0.11}S. Also note that the sixth (smallest bandgap) subcell is current limiting. This indicates lower external quantum efficiency than in the other subcells due to less efficient charge separation. The problem in this case is that the valence band of Cd_{0.16}Pb_{0.84}S is significantly higher than that of Ge, as shown in FIG. 3. This presents a barrier to hole extraction and tends to decrease the magnitude of the electric field in the nanowires, hindering charge separation. This can be seen in FIG. 5, which shows the band diagrams for all subcells operating at the maximum power point. Note that the bands in subcell 6 are relatively flat, indicating that it is operating reasonably close to the short-circuit point, as expected for the current-limiting subcell at the maximum power point of the overall LAMB solar cell.

The efficiencies shown in Table 2 are competitive with existing tandem cells (see, N. Lagos, M. M. Sigalas, and D. Niarchos, The optical absorption of nanowire arrays, Photonics and Nanostructures: Fundamentals and Applications (2010), doi: 10.1016/j.photonics 0.2010.09.005). A metamorphic GaInP/GaInAs/Ge tandem solar cell from Spectrolab achieved 40.7% efficiency at 240 suns, about 2% (absolute) less than that of the simulated LAMB solar cell. Additionally, due to the many layers that are deposited one-by-one to make these tandem cells, the fabrication of a lateral multijunction CdₓPb₁₋ₓS cell could potentially be much simpler and therefore less expensive. Potential improvements with respect to the BSF layers and charge separation could even increase the efficiency further. One such improvement would be to replace p-Ge with p-Si in the fourth subcell. This would increase the efficiencies shown in Table 2 to 35.5%, 41.3%, 42.6%, and 43.7% for concentration ratios of one, 25, 100, and 240 respectively, which represents a gain of nearly 1% (absolute) efficiency for the highest concentration ratio at the expense of greater complexity. Given materials with ideal band lineups to CdₓPb₁₋ₓS, efficiencies as high as 40.7%, 48.2%, 51.2%, and 53.1% were achieved in simulations for concentration ratios of one, 25, 100, and 240, respectively.

However, as previously mentioned, the conductivity in the CdₓPb₁₋ₓS nanowire layer may be lower than in a thin film, especially if the wires are randomly oriented and mostly in parallel to device layers. Therefore, these simulations were repeated with carrier mobilities reduced to 50% and 25% of their original values. The efficiencies with respect to mobility and solar concentration are shown in Table 2. The LAMB solar cell maintains sufficient performance even with the mobilities reduced by 50% to make it an attractive prospect for generating electricity.

TABLE 1
Efficiencies at various levels of solar concentration and with carrier
mobilities at 100%, 50%, and 25% of their original values

| Mobilities | Concentration | η | FF | V_{oc} (V) | J_{sc} (mA/cm²) |
|---|---|---|---|---|---|
| 100% | 1 | 34.9% | 78.3% | 4.593 | 8.739 |
| 100% | 25 | 40.5% | 79.6% | 5.236 | 218.6 |
| 100% | 100 | 41.7% | 77.3% | 5.556 | 874.1 |
| 100% | 240 | 42.7% | 74.7% | 5.899 | 2091 |
| 50% | 1 | 33.9% | 77.4% | 4.549 | 8.652 |
| 50% | 25 | 39.3% | 76.3% | 5.343 | 216.6 |
| 50% | 100 | 38.9% | 72.6% | 5.571 | 866.0 |
| 50% | 240 | 38.4% | 68.4% | 5.901 | 2058 |
| 25% | 1 | 32.5% | 77.0% | 4.473 | 8.487 |
| 25% | 25 | 37.5% | 74.9% | 5.287 | 212.9 |
| 25% | 100 | 35.4% | 66.1% | 5.663 | 851.0 |
| 25% | 240 | 32.1% | 66.9% | 5.597 | 1856 |

There are a number of possible approaches to fabricating LAMB cells using either randomly oriented or vertical nanowire arrays. Randomly oriented nanowires may be transferred to another substrate by contact printing (see, Z. Fan, J. C. Ho, Z. A. Jacobson, R. Yerushalmi, R. L. Alley, H. Razavi, and A. Javey, “Wafer-scale assembly of highly ordered semiconductor nanowire arrays by contact printing,” Nano Lett. 8(1), 20-25 (2008)) or the Langmuir-Blodgett technique (see, P. Yang and F. Kim, “Langmuir-Blodgett assembly of one-dimensional nanostructures,” Chem Phys Chem 3(6), 503-506 (2002)) to order them sufficiently before deposition of the contact materials. Spin-on-glass, Si₃N₄ or SiO₂ deposited by CVD can be used to isolate the p and n-type contacts. The insulating material can be etched to expose the nanowires prior to contact deposition to ensure good electrical contact. Alternatively, vertical nanowire arrays can be obtained using growth templates such as those made from anodized aluminum oxide (AAO). The AAO would serve essentially the same purpose as the dielectric material for the randomly oriented wires, isolating the p and n-type contact materials from each other and providing a planar surface for film deposition. The AAO can be etched using NaOH to expose the nanowires before depositing the contact materials to obtain better electrical contact (see, Z. Fan, H. Razavi, J. W. Do, A. Moriwaki, O. Ergen, Y. L. Chueh, P. W. Leu, J. C. Ho, T. Takahashi, L. A. Reichertz, S, Neale, K. Yu, M. Wu, J. W. Ager, and A. Javey, “Three-dimensional nanopillar-array photovoltaics on low-cost and flexible substrates,” Nat. Mater. 8(8), 648-653 (2009)).

We have proposed an integrated platform for the laterally arranged multiple bandgap solar cells to be integrated with low-cost, compact dispersive concentration optics for DCPV applications. A design study of LAMB solar cells using composition graded alloy nanowires has been conducted. This design was simulated using Silvaco ATLAS device simulation software, and the results demonstrate that spatially composition graded CdₓPb₁₋ₓS nanowires have the potential to deliver efficiencies competitive with the other high efficiency solar cells on the market today. Moreover, the ability to vary the bandgaps of these nanowires over a broad spectral range on a single substrate using the dual gradient growth method offers the possibility of significantly reducing manufacturing costs by simplifying the fabrication process. The proposed fabrication including deposition of doped contact layers and the growth of alloy nanowires can all be accomplished using low cost CVD methods. The potential for high performance and cost effective fabrication of LAMB solar cells based on this technology makes them an attractive prospect for decreasing the cost per watt of photovoltaic energy. Several other advantages of this approach are also worthy of mention, including the ability to easily and significantly increase the number of junctions and the flexibility to choose different connection schemes for the subcells (unlike tandem cells, which are restricted to series connections).

### Example 3

### Cell Designs

Methods of growing spatially composition-graded semiconductor alloy nanowires, allowing the bandgap energy to be varied continuously over a wide range across the surface of a single substrate with just a single CVD growth have been previously developed (see, A. L. Pan, R. Liu, M. Sun, and C. Z. Ning, Journal of the American Chemical Society 131, 9502-9503 (2009)). This technology can be applied to make an inexpensive and high efficiency solar cell by growing various subcells with different bandgaps side-by-side monolithically, rather than vertically stacked as in a more traditional tandem solar cell. This approach uses a separate optical element to split the incident sunlight into its spectral components and direct them towards the subcell with the most appropriate bandgaps.

Various composition graded CdₓPb₁₋ₓS nanowires or InₓGa₁₋ₓN can be used as absorbing material for such LAMB cells.

Such LAMB cells can be used in conjunction with several dispersive concentration optical technologies that are currently available in the literature, including the Sundialer technology developed at University of Delaware (Mike Haney) or holographic dispersive concentrators developed by Raymond Kostuk at University of Arizona or by Ludman et al. In the following, we use the holographic dispersive concentrator as an example to show how our LAMB cells can be used in conjunction with such dispersive concentrators to make integrated dispersive concentrator PV (DCPV) for low cost, highly efficient concentrator solar cells.

Work on holographic dispersive concentrators is ongoing at the University of Arizona under Prof. Raymond Kostuk (see, R. Kostuk, J. Castillo, J. M. Russo, and G. Rosenberg, Proc. of SPIE 6649, 66490I (2007)).

One design is to place LAMB cells on both sides of such staggered DC optics (see FIG. 6). This would allow easy integration of our LAMB cells with their optics. Our LAMB cells design is a very general approach covering a wide range of options such as cell materials which could be CdPbS or InGaN or any other multiple bandgap materials. Each cell can consist of thin films or nanowires or other types of materials. The contact materials can be varied accordingly.

Several specific designs have been analyzed, varying the contact materials, composition of the absorbing materials, number of subcells, method of charge separation, and doping profiles. The most notable of these are described below. The unifying features of these designs are the use of multiple laterally-arranged solar cells with different band gaps, CdₓPb₁₋ₓS alloy nanowires as the absorbing materials, and spectral splitting of the incident optical spectrum.

### Design 1

A laterally-arranged multiple bandgap (LAMB) solar cell using CdₓPb₁₋ₓS with six subcells having the properties shown in Table 3 was simulated using Silvaco software.

TABLE 3
Properties of LAMB solar cell design 1

| | | Assigned | | |
|---|---|---|---|---|
| | Bandgap | Spectral Range | Electron Affinity | |
| Subcell | (eV) | (μm) | (eV) | Composition |
| 1 | 2.32 | 0.28-0.533 | 4.45 | Cd_{0.96}Pb_{0.04}S |
| 2 | 1.92 | 0.534-0.645 | 4.22 | Cd_{0.76}Pb_{0.24}S |
| 3 | 1.65 | 0.646-0.752 | 4.06 | Cd_{0.63}Pb_{0.37}S |
| 4 | 1.43 | 0.753-0.867 | 3.93 | Cd_{0.52}Pb_{0.48}S |
| 5 | 1.21 | 0.868-1.018 | 3.80 | Cd_{0.41}Pb_{0.59}S |
| 6 | 1.03 | 1.019-1.200 | 3.69 | Cd_{0.33}Pb_{0.67}S |

A pn junction within each subcell was the mechanism for charge separation. The n-type region was placed on top and the p-type region on the bottom, with net donor and acceptor concentrations of 10¹⁸ cm⁻³ and 10¹⁷ cm⁻³ respectively. The contacts were assumed to exhibit ideal ohmic behavior, meaning that the contact resistance and resistance in the metal were assumed to be zero. The efficiency of this device when all subcells were connected in series was 25.1% without solar concentration and 28.2% at 100× solar concentration. Although the LAMB solar cell was illuminated with the AM1.5 direct spectrum only, the efficiencies reported above assume the input intensity equals the AM1.5 global spectrum

$$( η = \frac{{P}_{out}}{{P}_{i n}^{global}} ) .$$

This accounts for the loss of diffuse light within the dispersive concentrator. If these figures are recalculated using the intensity of AM1.5 direct spectrum with which the cells were illuminated

$$( η = \frac{{P}_{out}}{{P}_{i n}^{direct}} ) ,$$

the unconcentrated and 100 sun efficiencies increase to 27.9% and 31.4% respectively. The efficiencies with respect to the global and direct intensities will be henceforth referred to as the global reference and direct reference efficiencies, respectively. This is summarized in Table 4.

TABLE 4
Efficiencies for LAMB solar cell design 1

| Solar | Global-reference | Direct-reference |
|---|---|---|
| concentration ratio | efficiency | efficiency |
| 1 | 25.1% | 27.9% |
| 100 | 28.2% | 31.4% |

### Design 2

A second design using only five subcells has the properties shown in Table 5.

TABLE 5
Properties of LAMB solar cell design 2

| | | Assigned | | |
|---|---|---|---|---|
| | Bandgap | Spectral Range | Electron Affinity | |
| Subcell | (eV) | (μm) | (eV) | Composition |
| 1 | 2.11 | 0.28-0.587 | 4.33 | Cd_{0.86}Pb_{0.14}S |
| 2 | 1.66 | 0.588-0.746 | 4.06 | Cd_{0.64}Pb_{0.36}S |
| 3 | 1.35 | 0.747-0.92 | 3.88 | Cd_{0.48}Pb_{0.52}S |
| 4 | 1.05 | 0.921-1.179 | 3.70 | Cd_{0.34}Pb_{0.66}S |
| 5 | 0.77 | 1.180-1.606 | 3.54 | Cd_{0.20}Pb_{0.80}S |

In this design, the CdₓPb₁₋ₓS nanowires are intrinsic. Charge separation is achieved using highly doped semiconductor layers (N_{A}=N_{D}=10¹⁹ cm⁻³) just before the metal contacts, as described in Table 6. As in design 1, the metal contacts are assumed to exhibit ideal ohmic behavior.

TABLE 6
Semiconductor contacts for LAMB solar cell design 2

| Subcell | n-contact | p-contact |
|---|---|---|
| 1 | n-ZnS | p-ZnTe |
| 2 | n-ZnS | p-CdTe |
| 3 | n-ZnS | p-CdTe |
| 4 | n-ZnS | p-Si |
| 5 | n-ZnS | p-Ge |

The global and direct reference efficiencies are 30.5% and 33.9% without solar concentration. When simulated under 100× solar concentration, the efficiency declined dramatically. Replacing p-ZnTe with p-CdTe reduced this decline to approximately 3% absolute (27.2% and 30.3% global and direct reference efficiencies, respectively).

### Design 3

Some of the properties of a third design for the LAMB solar cell are shown in Table 7. The CdₓPb₁₋ₓS nanowires in this design are intrinsic, as in the second design, and highly doped (N_{A}=N_{D}=10¹⁹ cm⁻³) semiconductor contact materials are used to separate the charge carriers. The contact materials are listed by subcell in Table 8. The metal electrodes are assumed to exhibit ideal ohmic behavior.

TABLE 7
Properties of LAMB solar cell design 3

| | | Assigned | | |
|---|---|---|---|---|
| | Bandgap | Spectral Range | Electron Affinity | |
| Subcell | (eV) | (μm) | (eV) | Composition |
| 1 | 2.17 | 0.28-0.571 | 4.36 | Cd_{0.89}Pb_{0.11}S |
| 2 | 1.67 | 0.572-0.714 | 4.07 | Cd_{0.64}Pb_{0.36}S |
| 3 | 1.43 | 0.715-0.865 | 3.93 | Cd_{0.52}Pb_{0.48}S |
| 4 | 1.17 | 0.866-1.059 | 3.77 | Cd_{0.39}Pb_{0.61}S |
| 5 | 0.95 | 1.060-1.309 | 3.64 | Cd_{0.28}Pb_{0.72}S |
| 6 | 0.70 | 1.310-1.770 | 3.50 | Cd_{0.16}Pb_{0.84}S |

TABLE 8
Semiconductor contacts for LAMB solar cell design 3

| Subcell | n-contact | p-contact |
|---|---|---|
| 1 | n-ZnS | p-ZnTe |
| 2 | n-ZnS | p-ZnTe |
| 3 | n-ZnS | p-ZnTe |
| 4 | n-ZnS | p-Ge |
| 5 | n-ZnS | p-Ge |
| 6 | n-ZnS | p-Ge |

The performance of this device under various levels of solar concentration is described in Table 9.

TABLE 9
Performance of LAMB solar cell design 3

| Solar | Global- | Direct- | | | |
|---|---|---|---|---|---|
| Concentration | reference | reference | | | J_{sc} |
| Ratio | efficiency | efficiency | FF | V_{oc} (V) | (mA/cm²) |
| 1 | 31.4% | 34.9% | 78.3% | 4.593 | 8.739 |
| 25 | 36.4% | 40.4% | 79.6% | 5.236 | 218.6 |
| 100 | 37.5% | 41.7% | 77.3% | 5.556 | 874.1 |
| 240 | 38.4% | 42.7% | 74.7% | 5.899 | 2091 |

### Design 4:

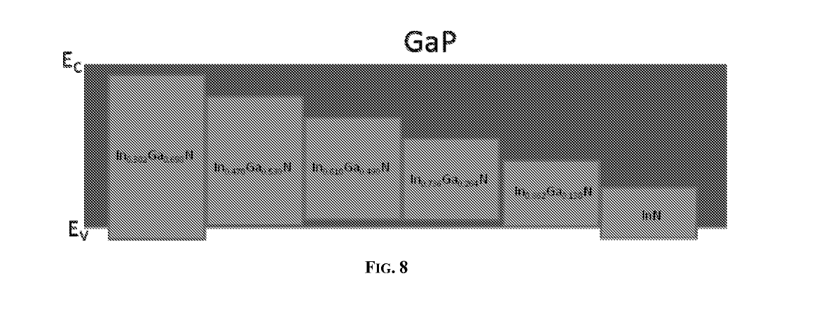

This design utilizes the n-type nanowires from the InGaN material system as the active absorber materials and their heterojunctions with p-GaP to separate the photogenerated electrical charge carriers. As shown in FIG. 8, the energy band alignment between InGaN and GaP is predicted to be favorable for extracting photogenerated holes from the valence band of InGaN within the composition ranges utilized. The InGaN compositions and related properties for all six subcells in this design are shown in Table 10, below. Simulations in Silvaco ATLAS under air mass zero illumination yielded the performance results shown in Table 11 when carrier recombination lifetimes are assumed to be 20 ns and doping concentrations of N_{A}=10¹⁹ cm⁻³ and N_{D}=10¹⁸ cm⁻³ are assumed of InGaN and GaP, respectively.

TABLE 10
Properties of LAMB solar cell design 4

| | | Assigned | | |
|---|---|---|---|---|
| | Bandgap | Spectral Range | Electron Affinity | |
| Subcell | (eV) | (μm) | (eV) | Composition |
| 1 | 2.28 | 0.28-0.544 | 3.94 | In_{0.30}Ga_{0.70}N |
| 2 | 1.78 | 0.5445-0.699 | 4.24 | In_{0.47}Ga_{0.53}N |
| 3 | 1.41 | 0.700-0.878 | 4.53 | In_{0.61}Ga_{0.39}N |
| 4 | 1.13 | 0.879-1.094 | 4.82 | In_{0.74}Ga_{0.26}N |
| 5 | 0.90 | 1.095-1.374 | 5.13 | In_{0.86}Ga_{0.14}N |
| 6 | 0.70 | 1.374-1.773 | 5.50 | InN |

TABLE 11
Performance of LAMB solar cell design 4

| Solar Concentration | AM0 reference | | | J_{sc} |
|---|---|---|---|---|
| Ratio | efficiency | FF | V_{oc} (V) | (mA/cm²) |
| 1 | 35.9% | 87.2% | 6.182 | 9.099 |
| 25 | 39.9% | 89.1% | 6.718 | 227.5 |
| 100 | 41.3% | 89.3% | 6.938 | 909.9 |
| 240 | 42.1% | 89.3% | 7.077 | 2184 |

### Design 5

This design is identical to design 4 except that an intrinsic InGaN region exists in the nanowires between the interface with p-GaP and an n-type n-InGaN region at the rear with N_{D}=10¹⁹ cm⁻³. Performance results for this design under air mass zero illumination and assuming charge carrier recombination lifetimes of 20 ns are shown in Table 12, below.

TABLE 12
Performance of LAMB solar cell design 5

| Solar Concentration | AM0 reference | | | J_{sc} |
|---|---|---|---|---|
| Ratio | efficiency | FF | V_{oc} (V) | (mA/cm²) |
| 1 | 33.2% | 88.5% | 5.097 | 10.04 |
| 25 | 38.8% | 88.0% | 5.993 | 251.0 |
| 100 | 41.3% | 87.8% | 6.407 | 1004 |
| 240 | 43.0% | 87.7% | 6.669 | 2410 |

The present invention is illustrated by way of the foregoing description and examples. The foregoing description is intended as a non-limiting illustration, since many variations will become apparent to those skilled in the art in view thereof. It is intended that all such variations within the scope and spirit of the appended claims be embraced thereby. Each referenced document herein is incorporated by reference in its entirety for all purposes.

Changes can be made in the composition, operation and arrangement of the method of the present invention described herein without departing from the concept and scope of the invention as defined in the following claims.

We claim:

1. A solar cell assembly comprising one or more laterally-arranged multiple bandgap (LAMB) solar cells and a dispersive concentrator positioned to provide light to the surfaces of each of the LAMB cells, wherein each LAMB cell comprises a plurality of laterally-arranged solar cells each having a different bandgap.

2. The assembly of claim 1, wherein at least one solar cell comprises an n-contact, a p-contact, and an intrinsic alloy layer disposed between the n-contact and the p-contact.

3. The assembly of claim 1, comprising two LAMB cells wherein the dispersive concentrator is disposed between the two LAMB cells.

4. The assembly of claim 2, wherein the intrinsic alloy layer of the solar cells comprises nanowires.

5. The assembly of claim 4, wherein the nanowires are CdₓPb₁₋ₓS nanowires, ZnₓCd_{y}Hg_{1-x-y}Te nanowires, AlₓGa_{y}In_{1-x-y}As nanowires, GaₓIn₁₋ₓP_{y}As_{1-y} nanowires, or InₓGa₁₋ₓN nanowires.

6. The assembly of claim 4, wherein the nanowires are spatially-composition graded nanowires.

7. The assembly of claim 1, wherein the dispersive concentrator comprises the same number of spectrally selective holographic planar concentrators as the number of solar cells in each LAMB cell.

8. The assembly of claim 7, wherein each spectrally selective holographic planar concentrator is in optical communication with only one solar cell of each LAMB, wherein the solar cells in communication with each spectrally selective holographic planar concentrator have essentially the same bandgap.

9. The assembly of claim 7, wherein the wavelengths of light selected by each spectrally selective holographic planar concentrator correspond to the bandgap of the solar cell in optical communication with the spectrally selective holographic planar concentrator.

10. The assembly of claim 1, wherein each of the solar cells has a bandgap between about 0.5 eV and about 3.0 eV.

11. The assembly of claim 2, wherein the n-contact for each of the solar cells independently comprises an n-CdS, n-ZnSe or n-ZnS layer.

12. The assembly of claim 2, wherein the p-contact for each of the solar cells independently comprises a p-ZnTe, p-CdTe, p-Si, or p-Ge layer.

13. The assembly of claim 1, wherein at least one solar cell comprises a heterojunction p-n junction.

14. The assembly of claim 13, wherein the n-layer of the heterojunction p-n junction comprises nanowires.

15. The assembly of claim 14, wherein the nanowires are n-doped CdₓPb₁₋ₓS nanowires, n-doped ZnₓCd_{y}Hg_{1-x-y}Te nanowires, n-doped AlₓGa_{y}In_{1-x-y}As nanowires, n-doped GaₓIn₁₋ₓP_{y}As_{1-y} nanowires, or n-doped InₓGa₁₋ₓN nanowires.

16. The assembly of claim 15, wherein the p-layer of the heterojunction p-n junction comprises p-GaP.

17. The assembly of claim 1, wherein at least one solar cell comprises a heterojunction p-i-n junction.

18. The assembly of claim 17, wherein the n-layer and the i-layer of the heterojunction p-i-n junction comprises nanowires.

19. The assembly of claim 18, wherein the n-layer comprises n-doped CdₓPb₁₋ₓS nanowires, n-doped ZnₓCd_{y}Hg_{1-x-y}Te nanowires, n-doped AlₓGa_{y}In_{1-x-y}As nanowires, n-doped GaₓIn₁₋ₓAs_{1-y} nanowires, or n-doped InₓGa₁₋ₓN nanowires; and the i-layer comprises the same alloy composition as the n-layer.

20. The assembly of claim 19, wherein the p-layer of the heterojunction p-i-n junction comprises p-GaP.
